(19) United States
(12) Patent Application Publication
(10) Pub. No.: US 2023/0279545 A1
(43) Pub. Date: Sep. 7, 2023

(54) PROCESS FOR PREPARING SILICON-RICH SILICON NITRIDE FILMS

(71) Applicant: ENTEGRIS, INC., Billerica, MA (US)

(72) Inventors: Philip S. H. Chen, Bethel, CT (US); Shawn Duc Nguyen, Danbury, CT (US); Bryan C. Hendrix, Danbury, CT (US)

(21) Appl. No.: 18/117,183

(22) Filed: Mar. 3, 2023

Related U.S. Application Data
(60) Provisional application No. 63/316,956, filed on Mar. 4, 2022.

(51) Int. Cl. C23C 16/455; H01L 21/02; C23C 16/34

(52) U.S. Cl. CPC C23C 16/45553; H01L 21/0217; H01L 21/02211; H01L 21/02271; C23C 16/45536; C23C 16/345

(57) ABSTRACT

In summary, the invention provides a process for depositing a silicon nitride film onto a microelectronic device substrate. The process utilizes precursors and co-reactants chosen from a halosilane compound, a compound of the formula R₂NH, an amino-silane, and hydrogen. The silicon nitride films so formed have increased proportions of silicon, while providing uniform thickness films, i.e., high conformality, even in high aspect 3D NAND structures.

### PRIORITY CLAIM

This document claims priority to U.S. provisional patent application No. 63/316,956 with a filing date of Mar. 4, 2022. The priority document is incorporated by reference herein for all purposes.

### TECHNICAL FIELD

The invention relates generally to a process for depositing silicon-rich nitride films on microelectronic device substrates.

### BACKGROUND

Silicon nitride is commonly used in the fabrication of integrated circuits. For example, it is often used as an insulating material in the manufacturing of various microelectronic devices such as memory cells, logic devices, memory arrays, etc. In particular, silicon nitride is used as a charge trap layer in 3D NAND structures. Silicon nitride has a general empirical formula of Si₃N₄, but in any given deposited film, this composition may vary and in certain applications, a silicon-rich silicon nitride film is desired. Current processes utilize hexachlorodisilane (HCDS) precursor and ammonia co-reactant as silicon and nitrogen sources. These HCDS/ammonia processes can provide the desired silicon-rich stoichiometry, but the deposited silicon nitride films lack desired conformality. Atomic layer deposition (ALD) and pulsed Chemical Vapor Deposition (CVD) processes utilizing HCDS/ammonia can provide films with good conformality, but not the desired silicon:nitrogen stoichiometry. Accordingly, a process which could produce uniform thickness (i.e., highly conformal) films having a silicon:nitrogen composition>1 in high aspect 3D NAND structures would be greatly desired.

### SUMMARY

In summary, the invention provides a process for depositing a silicon nitride film onto a microelectronic device substrate. The process utilizes precursors and co-reactants chosen from a halosilane compound, a compound of the formula R₂NH, an amino-silane, and hydrogen. The silicon nitride films so formed have increased stoichiometric proportions of silicon, while providing uniform thickness films, i.e., high conformality, even in high aspect ratio 3D NAND structures.

### BRIEF DESCRIPTION OF THE DRAWINGS

FIG. 1 is a plot of growth rate per cycle (GPC) in angstroms per cycle versus the pulse time of hexachlorodisilane (HCDS). (See Example 1). The circular data points represent a pulse sequence of HCDS/NH₃. The triangle data points represent a pulse sequence of HCDS/(4DMAS+H₂)/NH₃. The diamond data points represent a pulse sequence of HCDS/4DMAS/NH₃. The square data points represent a pulse sequence of HCDS/4DMAS/(NH₃+H₂).

FIG. 2 is a plot of ellipsometry (SE) thickness in angstroms versus etch time in minutes for various pulse sequences (See Example 2). The triangle points relate to a thermal oxide film. The circle points relate to a HCDS/NH₃ pulse sequence. The diamond points relate to a HCDS/(4DMAS)+H₂)/NH₃ pulse sequence. The square points relate to a HCDS/4DMAS/(NH₃+H₂) pulse sequence.

FIG. 3 depicts the atomic concentration of silicon, nitrogen, oxygen, chlorine, and carbon, at varying depths of the film (in nanometers). (See Example 3).

FIG. 4 depicts the atomic concentration of silicon, nitrogen, oxygen, chlorine, and carbon, at varying depths of the film (in nanometers). (See Example 3).

FIG. 5 is a plot of growth rate per cycle (GPC) in angstroms per cycle versus pulse time of HCDS in seconds. The square data points represent a pulse sequence of HCDS/4DMAS/(NH₃+H₂). The diamond points represent a pulse sequence of HCDS/(NH₃+H₂). The circular data points represent a pulse sequence of HCDS/NH₃. (See Example 4).

FIG. 6 depicts the atomic concentration of silicon, nitrogen, oxygen, chlorine, and carbon, at varying depths of the film (in nanometers). (See Example 5).

FIG. 7 depicts the atomic concentration of silicon, nitrogen, oxygen, chlorine, and carbon, at varying depths of the film (in nanometers). (See Example 5).

FIG. 8 is a plot of SE thickness in angstroms versus etch time in minutes. The triangle points represent a thermal oxide reference film. The circle points relate to a film resulting from a HCDS/4DMAS pulse sequence at 600° C. (See Example 7).

FIG. 9 a plot of SE thickness in angstroms versus etch time in minutes. The triangle points represent a thermal oxide reference film. The circle points represent a film prepared from a HCDS/4DMAS pulse sequence at 570° C. (See Example 7).

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a process for depositing a silicon nitride film on a microelectronic device substrate, which comprises contacting said substrate with sequentially pulsed precursor compounds comprising a pulse sequence comprising:
a. halo silane compound,
b. an amino-silane, and optionally
c. a compound of the formula R₂NH, wherein each R is independently hydrogen or a C₁-C₄ alkyl group, in combination with hydrogen,
under vapor deposition conditions.

In a second aspect, the invention provides a process for depositing a silicon nitride film on a microelectronic device substrate, which comprises contacting said substrate with sequentially pulsed precursor compounds comprising a pulse sequence comprising:
a. halo silane compound, and
b. a compound of the formula R₂NH, wherein each R is independently hydrogen or a C₁-C₄ alkyl group, in combination with hydrogen,
under vapor deposition conditions.

In the above aspects, the amino-silane compound is a nitrogen precursor compound comprising at least one silicon atom and at least one alkylamino group. Exemplary amino-silane compounds include compounds of the formula

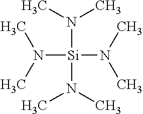

tetrakis(dimethylamino)silane (CAS No. 1624-01-7);

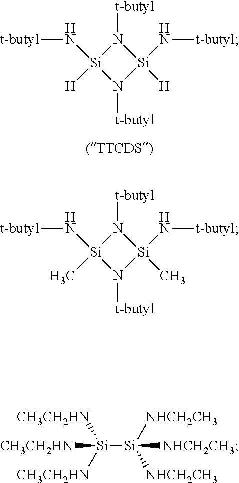

(hexakis(ethylamino)disilane) (CAS No. 532980-53-3); and a compound of the formula:

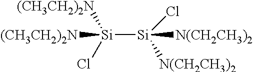

1,2-dichloro-N, N, N′,N′, N″,N″, N′″, N′″-octaethyl-1,1,2,2-disilanetetramine “EACDS” (CAS No. 151625-20-6).

In the above aspects, the halo silane compound is a silicon precursor compound containing one or two silicon atoms and at least one halogen atom, such as chlorine, bromine, or iodine. In certain embodiments, the halo silane compound is chosen from chlorosilane, iodosilane, diiodosilane, and hexachlorodisilane.

The compounds of the formula R₂NH include ammonia, dimethylamine, diethylamine, and the like. In one embodiment, the compound of the formula R₂NH is ammonia.

In certain embodiments, the pulse sequence will be chosen from the following:
a. hexachlordisilane/purge/tetrakis(dimethylamino)silane/purge/(NH₃+H₂)/purge
b. hexachlorodisilane/purge/(tetrakis(dimethylamino)silane+H₂)/purge/NH₃/purge
c. hexachlorodisilane/purge/tetraks(dimethylamino)silane/purge/NH₃/purge
d. chlorosilane/purge/tetrakis(dimethylamino)silane/purge/(NH₃+H₂)/purge
e. chlorosilane/purge/(tetrakis(dimethylamino)silane+H₂)/purge/NH₃/purge
f. chlorosilane/purge/tetraks(dimethylamino)silane/purge/NH₃/purge
g. iodosilane/purge/tetrakis(dimethylamino)silane/purge/(NH₃+H₂)/purge
h. iodosilane/purge/(tetrakis(dimethylamino)silane+H₂)/purge/NH₃/purge
i. iodosilane/purge/tetraks(dimethylamino)silane/purge/NH₃/purge
j. diiodosilane/purge/tetrakis(dimethylamino)silane/purge/(NH₃+H₂)/purge
k. diiodosilane/purge/(tetrakis(dimethylamino)silane+H₂)/purge/NH₃/purge
l. diiodosilane/purge/tetraks(dimethylamino)silane/purge/NH₃/purge
m. hexachlordisilane/purge/TTCDS/purge/(NH₃+H₂)/purge
n. hexachlorodisilane/purge/TTCDS+H₂)/purge/NH₃/purge
o. hexachlorodisilane/purge/TTCDS/purge/NH₃/purge
p. chlorosilane/purge/TTCDS/purge/(NH₃+H₂)/purge
q. chlorosilane/purge/TTCDS+H₂)/purge/NH₃/purge
r. chlorosilane/purge/TTCDS/purge/NH₃/purge
s. iodosilane/purge/TTCDS/purge/(NH₃+H₂)/purge
t. iodosilane/purge/TTCDS+H₂)/purge/NH₃/purge
u. iodosilane/purge/TTCDS/purge/NH₃/purge
v. diiodosilane/purge/TTCDS/purge/(NH₃+H₂)/purge
w. diiodosilane/purge/TTCDS+H₂)/purge/NH₃/purge
x. diiodosilane/purge/hexachlordisilane/purge/tetrakis(dimethylamino)silane/purge/(NH₃+H₂)/purge
y. hexachlordisilane/purge/EACDS/purge/(NH₃+H₂)/purge
z. hexachlorodisilane/purge/EACDS+H₂)/purge/NH₃/purge
aa. hexachlorodisilane/purge/EACDS/purge/NH₃/purge
bb. chlorosilane/purge/EACDS/purge/(NH₃+H₂)/purge
cc. chlorosilane/purge/EACDS+H₂)/purge/NH₃/purge
dd. chlorosilane/purge/EACDS/purge/NH₃/purge
ee. iodosilane/purge/EACDS/purge/(NH₃+H₂)/purge
ff. iodosilane/purge/EACDS+H₂)/purge/NH₃/purge
gg. iodosilane/purge/EACDS/purge/NH₃/purge
hh. diiodosilane/purge/EACDS/purge/(NH₃+H₂)/purge
ii. diiodosilane/purge/EACDS+H₂)/purge/NH₃/purge
jj. diiodosilane/purge/EACDS/purge/NH₃/purge
   /NH₃/purge

The process of the invention enables the deposition of highly conformal silicon nitride films having an enhanced proportion of silicon, i.e., a proportion of silicon greater than the typical Si₃N₄ stoichiometry (on a molar basis). In certain embodiments, the proportion of silicon to nitrogen in such films is greater than 3:4. In other embodiments, the silicon:nitrogen ratio is greater than 1:1, such as 1.04:1, or 1.12:1 (in other words, 1.12 parts of silicon versus one part nitride).

Additionally, the process of the invention enables the deposition of such silicon nitride films having high conformality, e.g., at least about 92%, at least about 93%, at least about 94%, or at least about 95% step coverage on a trench structure with an aspect ratio of about 12. The step coverage is calculated with film thickness at the trench bottom divided by film thickness at trench top.

As noted above, the process of the invention enables the deposition of silicon nitride films having am enhanced or increased silicon proportion, while having excellent conformality, thus enabling facile deposition on high aspect ratio microelectronic devices. Thus, in another aspect, the invention provides a microelectronic device structure having thereon a silicon nitride film, the structure having at least one substructure having an aspect ratio of about greater than about 10, wherein the silicon nitride film has a conformality of at least about 95%, and a silicon to nitride ratio of at least about 1.04:1 to about 1.12:1. In certain embodiments, the device possesses an aspect ratio of from about 10 to about 500, and in other embodiments about 50 to about 200.

In certain embodiments, the vapor deposition conditions referred to herein comprise reaction conditions known as chemical vapor deposition, pulsed-chemical vapor deposition, and atomic layer deposition. In the case of pulsed-chemical vapor deposition, a series of alternating pulses of the precursor composition and co-reactant(s), either with or without an intermediate (inert gas) purge step, can be utilized to build up the film thickness to a desired endpoint.

In certain embodiments, the pulse time (i.e., duration of precursor exposure to the substrate) for the precursor compounds depicted above ranges between about 1 and 30 seconds. When a purge step is utilized, the duration is from about 1 to 20 seconds or 1 to 30 seconds. In other embodiments, the pulse time for the co-reactant ranges from 5 to 60 seconds.

In one embodiment, the vapor deposition conditions comprise a temperature in the reaction zone of about 400° C. to about 750° C., or about 500° C. to about 650° C., and at a pressure of about 0.2 Torr to about 100 Torr. It should be understood that the temperature of the reaction zone is also the temperature to which the microelectronic device substrate has been heated.

The desired microelectronic device substrate may be placed in a reaction zone in any suitable manner, for example, in a single wafer CVD or ALD, or in a furnace containing multiple wafers.

In one alternative, the processes of the invention can be conducted as an ALD or ALD-like process. As used herein, the terms “ALD or ALD-like” refer to processes such as (i) each reactant including the precursor composition comprising the compounds set forth herein, the co-reactant(s) are introduced sequentially into a reactor such as a single wafer ALD reactor, semi-batch ALD reactor, or batch furnace ALD reactor, or (ii) each reactant is exposed to the substrate or microelectronic device surface by moving or rotating the substrate to different sections of the reactor and each section is separated by an inert gas curtain, i.e., spatial ALD reactor or roll to roll ALD reactor. In certain embodiments, the thickness of the resulting bulk ALD silicon nitride film may be from about 0.5 nm to about 40 nm.

The deposition methods disclosed herein may involve one or more purge gases. The purge gas, which is used to purge away unconsumed reactants and/or reaction by-products, is an inert gas that does not react with either the precursor composition or the counter-reactant(s). Exemplary purge gases include, but are not limited to, argon, nitrogen, helium, neon, and mixtures thereof. In certain embodiments, a purge gas such as Ar is supplied into the reactor at a flow rate ranging from about 10 to about 2000 sccm for about 0.1 to 1000 seconds, thereby purging the unreacted material and any by-product that may remain in the reactor. Such purge gases may also be utilized as inert carrier gases for either or both of the precursor composition and co-reactant(s).

Energy is applied to the precursor composition and the co-reactant(s) in the reaction zone to induce reaction and to form the film on the microelectronic device surface. Such energy can be provided by, but not limited to, thermal, pulsed thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated ‘remotely’ of the reaction zone and substrate, being supplied into the reactor.

In one embodiment, the vapor phase deposition conditions comprise thermal atomic layer deposition conditions. In one embodiment, the thermal atomic layer deposition conditions further comprises the utilization of one or more periodic pulses of ammonia plasma and/or hydrogen plasma.

As used herein, the term “microelectronic device” corresponds to semiconductor substrates, including 3D NAND structures, flat panel displays, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly. Such microelectronic devices contain at least one substrate, which can be chosen from, for example, tin, SiO₂, Si₃N₄, OSG, FSG, tin carbide, hydrogenated tin carbide, tin nitride, hydrogenated tin nitride, tin carbonitride, hydrogenated tin carbonitride, boronitride, antireflective coatings, photoresists, germanium, germanium-containing, boron-containing, Ga/As, a flexible substrate, porous inorganic materials, metals such as copper and aluminum, and diffusion barrier layers such as but not limited to TiN, Ti(C)N, TaN, Ta(C)N, Ta, W, or WN.

### EXAMPLES

### Example 1 ALD Saturation

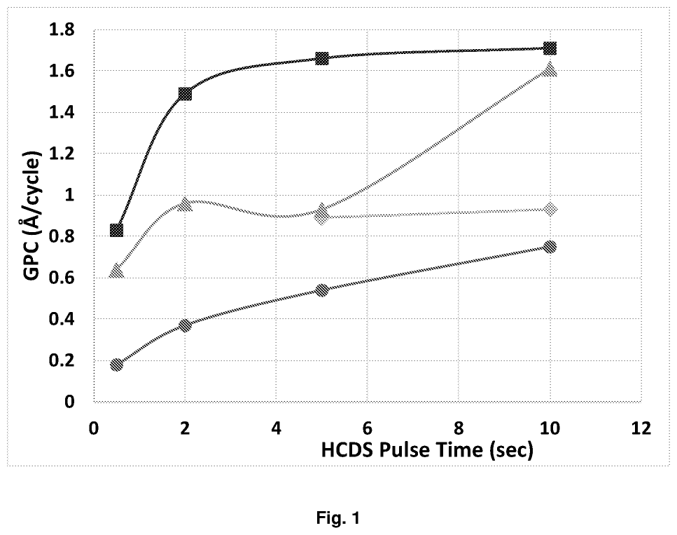

Referring to the data depicted in FIG. 1, atomic layer depositions were conducted on a silicon coupon at 600° C., in a chamber at a pressure of 2 Torr. A two-inch diameter shower head was utilized over a 4 cm silicon coupon. Hexachlorodisilane (HCDS) was introduced at a temperature of 18° C., along with tetrakis(dimethylamino)silane (CAS NO. 1624-01-7) (4DMAS) at a temperature of 22° C. Fifty cycles were conducted.

The following pulse sequences were conducted as set forth in FIG. 1:
a. HCDS/purge/4DMAS/purge/(NH₃+H₂)/purge
b. HCDS/purge/(4DMAS+H₂)/purge/NH₃/purge
c. HCDS/purge/4DMAS/purge/NH₃/purge
d. HCDS/purge/NH₃/purge
   i. Argon purge—5 second duration
   ii. 4DMAS introduction—2 second duration
   iii. NH₃ introduction—5 second duration
   iv. NH₃ flow rate 68 sccm
   v. H₂ flow rate 118 sccm

This data shows that the addition of 4DMAS pulses and H₂ to HCDS/NH₃ ALD regimes achieves saturation and higher growth rate. In this context, saturation means that the deposition rate is not changing with reactant pulse time, i.e., the deposition is self-limiting.

### Example 2—Etch Rate

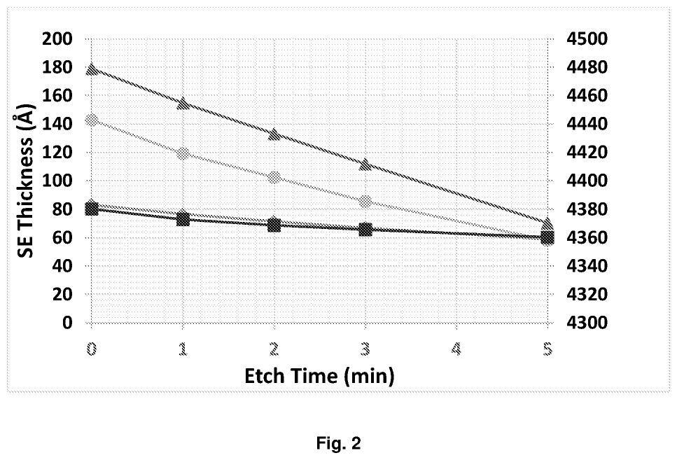

Referring to the data depicted in FIG. 2, SE Thickness in Angstroms is plotted versus etch time in minutes for a 100:1 dilute HF etch rate test. Data sets a. through d. are as follows:
a. HCDS/NH₃
b. HCDS/(4DMAS+H₂)/NH₃
c. HCDS/4DMAS/(NH₃+H₂)
d. Thermal Oxide

The wet etch rates (WER) (Å/minute) for the films so produced were as follows:
a. HCDS/NH₃—13.7
b. HCDS/(4DMAS+H₂)/NH₃—4.0
c. HCDS/4DMAS/(NH₃+H₂)—2.6
d. Thermal oxide—21.0

This data shows that the addition of 4DMAS pulses and H₂ to HCDS/NH₃ ALD regimes reduces wet etch rates of the resulting silicon nitride film so produced.

### Example 3—XPS Data

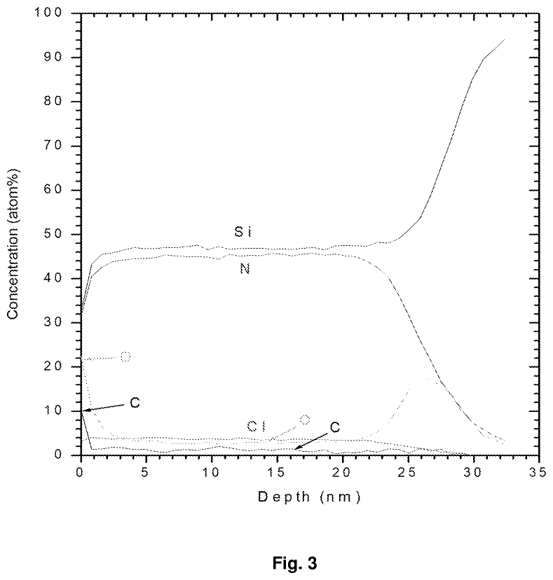

Referring to the data depicted in FIG. 3, a silicon rich film was deposited using atomic layer deposition at 600° C., and 2 Torr using a pulse regime of HCDS/4DMAS/(NH₃+H₂). This data shows 47 atomic percentage silicon, 45.2 atomic percentage of nitrogen, 1.2 atomic percentage of carbon, 2.9 atomic percentage of oxygen, and 3.7 atomic percentage of chlorine, with a silicon to nitrogen ratio of 1.04:1. The concentration (atomic percentage) is plotted versus depth in nanometers.

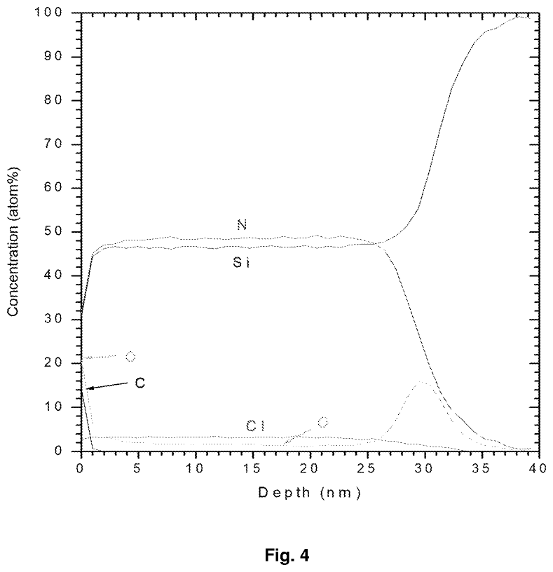

Referring to the data depicted in FIG. 4, a control film was produced under the same conditions using a pulse regime of HCDS/NH₃, to provide a film having 46.5 atomic percentage of silicon, 48.6 atomic percentage of nitrogen, 0 atomic percentage of carbon, 1.6 atomic percentage of oxygen, and 3.3 atomic percentage of chlorine, with a silicon to nitrogen ratio of 0.96:1.

This data shows that the addition of 4DMAS/H₂ pulses to HCDS deposits silicon rich silicon nitride film, while also introducing carbon.

### Example 4—Control Example Showing Saturation

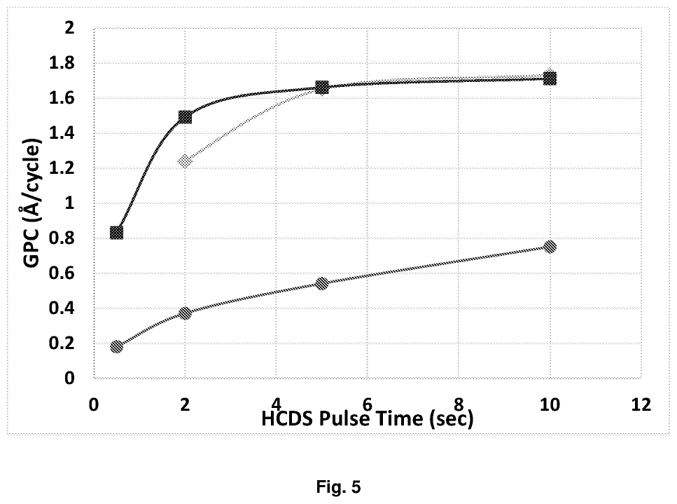

Referring to the data depicted in FIG. 5, an atomic layer deposition onto a coupon of silicon and was conducted at the same conditions as in Example 1, using the following pulse regimes:
a. HCDS/purge/4DMAS/purge/(NH₃+H₂)/purge
b. HCDS/purge/NH₃/purge
c. HCDS/purge/(NH₃+H₂)/purge

Growth rate (Å/cycle) was plotted versus HCDS pulse time in seconds. This data illustrates that an atomic layer deposition using an HCDS/(NH₃+H₂) regime (with or without 4DMAS) achieves saturation at 5 seconds of HCDS pulse.

### Example 5—NH₃/H₂

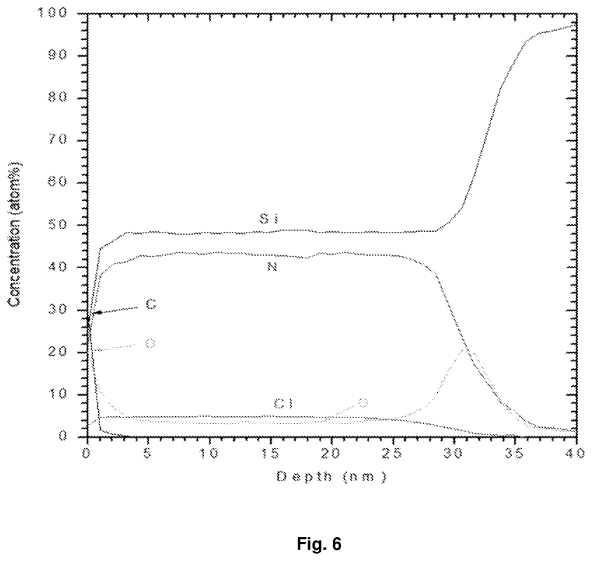

Referring to the data depicted in FIG. 6, a film of silicon nitride was deposited using the process parameters of Example 1, while using a pulse regime of HCDS/(NH₃+H₂), provided a silicon nitride film having 48.5 atomic percent of silicon, 43.2 atomic percent of nitrogen, 0 atomic percentage of carbon, 3.6 atomic percentage of oxygen, and 4.7 atomic percentage of chlorine, with a silicon to nitrogen ratio of 1.12:1.

Referring to the data depicted in FIG. 4, a film of silicon nitride was deposited using the process parameters of Example 1, while using a pulse regime of HCDS/NH₃, as a comparative example. This film had 46.5 percent of silicon, 48.6 atomic percent of nitrogen, 0 atomic percent of carbon, 1.6 atomic percent of oxygen, and 3.3 atomic percent of chlorine, with a silicon to nitrogen ratio of 0.96:1. This experiment shows that the NH₃+H₂ pulsing regime increases the silicon:nitrogen ratio while not adding carbon to the film.

### Example 6—HCDS/4DMAS

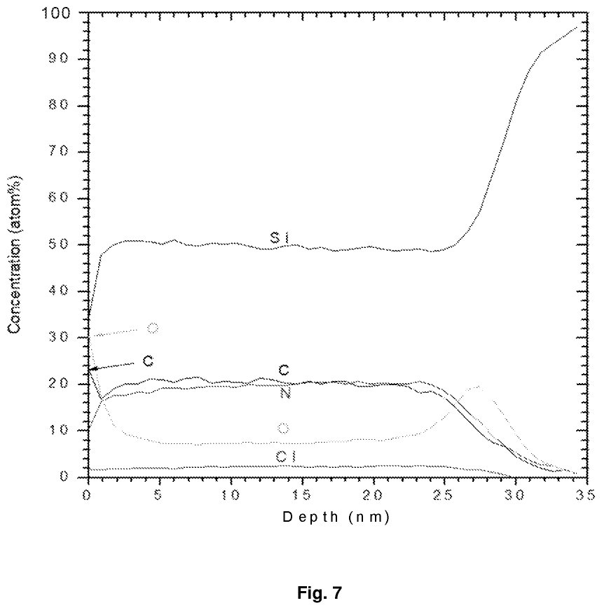

Referring to the data depicted in FIG. 7, a film of silicon nitride was deposited using the process parameters of Example 1, while using a pulse regime of HCDS/4DMAS, provided a film having 49.7 atomic percent of silicon, 19.9 atomic percent of nitrogen, 20.5 atomic percent of carbon, 7.5 atomic percent of oxygen, and 2.4 atomic percent of chlorine, with a silicon to nitrogen ratio of 2.5:1.

Referring to the data depicted in FIG. 4, a film of silicon nitride was deposited using the process parameters of Example 1, while using a pulse regime of HCDS/NH₃ as a comparative example. This film had 46.5 atomic percent of silicon, 48.6 atomic percent of nitrogen, 0 atomic percent of carbon, 1.6 atomic percent of oxygen, and 3.3 atomic percent of chlorine, with a silicon:nitrogen ratio of 0.96:1. This data shows that a pulse regime using HCDS/4DMAS improves the silicon to nitrogen ratio, a significant amount of carbon is also introduced into the film.

### Example 7—Comparison of Etch Rates

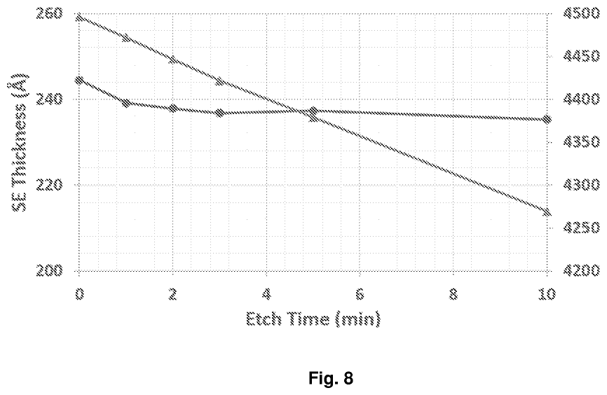

The data depicted in FIG. 8 illustrates the wet etch rate for a 100:1 dilute HF solution on a film prepared using an HCDS/4DMAS atomic layer deposition at 600° C., 2 Torr, 5 second 4DMAS pulse. This data shows a bulk wet etch rate of about 0.4 Å/minute.

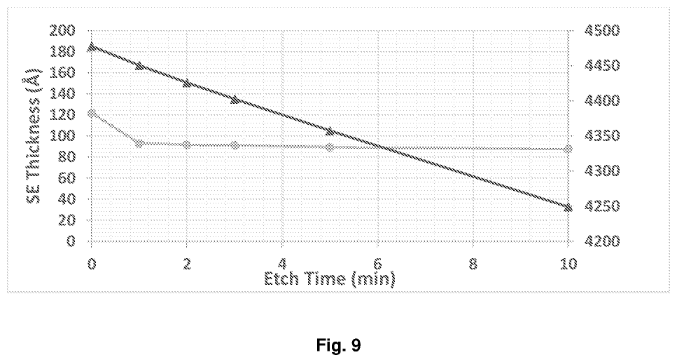

The data depicted in FIG. 9 illustrates the wet etch rate for a 100:1 dilute HF solution on a film prepared using HCDS/4DMAS atomic layer deposition at 570° C. and 2 Torr. This data shows a bulk wet etch rate of 0.36 Å/minute.

SUMMARY TABLE I

| | | Growth | | XPS | 100:1 DHF | | |
|---|---|---|---|---|---|---|---|
| | | Per Cycle | | atomic | Wet Etch | AR12 | |
| | T | (GPC) | XPS | percentage | Rate | S/C | |
| ALD Process | (° C.) | Å/cycle | Si/N | Carbon | (Å/minute) | (%) | Comment |
| HCDS/NH₃ | 600 | 0.54 | 0.96 | 0 | 13.7 | — | Baseline |
| HCDS/4DMAS/ | 600 | 1.65 | 1.04 | 1.2 | 2.6 | >95 | Silicon rich but |
| (NH₃ + H₂) | | | | | | | contains carbon |
| HCDS/(NH₃ + H₂) | 600 | 1.66 | 1.12 | 0 | 14.1 | >96 | Clean silicon-rich |
| HCDS/4DMAS | 600 | 1.5 | 2.50 | 20.5 | 0.4 | — | Patterning layer |
| HCDS/4DMAS | 570 | 0.2 | — | — | 0.34 | ~94 | Patterning layer |

This data shows that the addition of tetrakis(dimethylamino)silane to a pulse sequence and the addition of hydrogen to a conventional hexachlordisilane/ammonia ALD process achieves saturation, increases the silicon content (i.e., increases the Silicon:Nitrogen ratio, and increases growth rate.

Aspects

In a first aspect, the invention provides a process for depositing a silicon nitride film on a microelectronic device substrate, which comprises contacting said substrate with sequentially pulsed precursor compounds comprising a pulse sequence comprising:
a. halo silane compound,
b. an amino-silane, and optionally
c. a compound of the formula R₂NH, wherein each R is independently hydrogen or a C₁-C₄ alkyl group, in combination with hydrogen,
under vapor deposition conditions.

In a second aspect, the invention provides a process for depositing a silicon nitride film on a microelectronic device substrate, which comprises contacting said substrate with sequentially pulsed precursor compounds comprising a pulse sequence comprising:
a. a halo silane compound, and
b. a compound of the formula R₂NH, wherein each R is independently hydrogen or a C₁-C₄ alkyl group, in combination with hydrogen,
under vapor deposition conditions.

In a third aspect, the invention provides the process of the first or second aspect, wherein a., b., and/or c. are followed by a purge step with an inert gas.

In a fourth aspect, the invention provides the process of any one of the first, second, or third aspects, wherein the halo silane compound is hexachlorodisilane.

In a fifth aspect, the invention provides the process of the first or third aspect, wherein the amino-silane is a compound of the formula

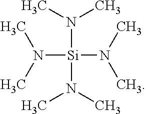

In a sixth aspect, the invention provides the process of the first or third aspect, wherein the amino-silane is a compound of the formula

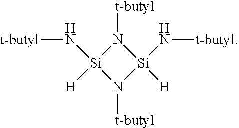

In a seventh aspect, the invention provides the process of the first or third aspect, wherein the amino-silane is a compound of the formula

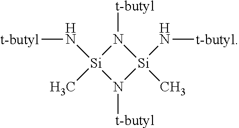

In an eighth aspect, the invention provides the process of the first or third aspect, wherein the amino-silane is a compound of the formula

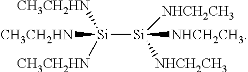

In a ninth aspect, the invention provides the process of the first or third aspect, wherein the amino-silane is a compound of the formula

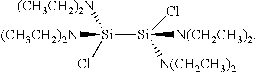

In a tenth aspect, the invention provides the process of any one of the first through the ninth aspects, wherein the silicon nitride film comprises a silicon:nitrogen ratio of at least about 3.1:4.

In an eleventh aspect, the invention provides the process of any one of the first through ninth aspects, wherein the silicon nitride film comprises a silicon:nitrogen ratio of greater than or equal to about 1:1.

In a twelfth aspect, the invention provides the process of the first or third aspects, wherein the pulse sequence comprises:

hexachlordisilane/purge/tetrakis(dimethylamino)silane/purge/(NH₃+H₂)/purge.

In a thirteenth aspect, the invention provides the process of the first aspect, wherein the pulse sequence comprises:

hexachlorodisilane/purge/(tetrakis(dimethylamino)silane+H₂)/purge/NH₃/purge.

In a fourteenth aspect, the invention provides the process of the first aspect, wherein the pulse sequence comprises:

hexachlorodisilane/purge/tetrakis(dimethylamino)silane/purge/NH₃/purge.

In a fifteenth aspect, the invention provides the process of the second aspect, wherein the pulse sequence comprises hexachlordisilane/purge/(NH₃+H₂)/purge.

In a sixteenth aspect, the invention provides the process of the first aspect, wherein the pulse sequence comprises hexachlorodisilane, tetrakis(dimethylamino)silane, and a mixture of ammonia and hydrogen.

In a seventeenth aspect, the invention provides the process of any one of the first through sixteenth aspects, further comprising at least one pulse sequence comprising plasma ammonia or plasma hydrogen.

In an eighteenth aspect, the invention provides the process of any one of the first through seventeenth aspects, wherein the silicon nitride film has a conformality of at least about 95%.

In a nineteenth aspect, the invention provides a microelectronic device structure having thereon a silicon nitride film, the structure having at least one substructure having an aspect ratio of about greater than about 10, wherein the silicon nitride film has a conformality of at least about 95%, and a silicon to nitride ratio of at least about 1.04:1 to about 1.12:1

In a twentieth aspect, the invention provides the device of the nineteenth aspect, wherein the aspect ratio is from about 10 to about 500.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A process for depositing a silicon nitride film on a microelectronic device substrate, which comprises contacting said substrate with sequentially pulsed precursor compounds comprising a pulse sequence comprising:
a. halo silane compound,
b. an amino-silane, and optionally
c. a compound of the formula R₂NH, wherein each R is independently hydrogen or a C₁-C₄ alkyl group, in combination with hydrogen,
under vapor deposition conditions.

2. A process for depositing a silicon nitride film on a microelectronic device substrate, which comprises contacting said substrate with sequentially pulsed precursor compounds comprising a pulse sequence comprising:
a. a halo silane compound, and
b. a compound of the formula R₂NH, wherein each R is independently hydrogen or a C₁-C₄ alkyl group, in combination with hydrogen,
under vapor deposition conditions.

3. The process of claim 1, wherein a., b., and/or c. are followed by a purge step with an inert gas.

4. The process of claim 1, wherein the halo silane compound is hexachlorodisilane.

5. The process of claim 1, wherein the amino-silane is a compound of the formula

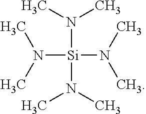

6. The process of claim 1, wherein the amino-silane is a compound of the formula

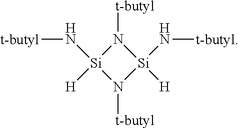

7. The process of claim 1, wherein the amino-silane is a compound of the formula

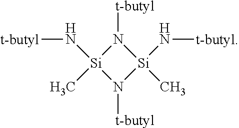

8. The process of claim 1, wherein the amino-silane is a compound of the formula

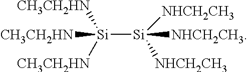

9. The process of claim 1, wherein the amino-silane is a compound of the formula

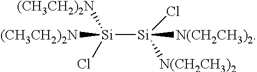

10. The process of claim 1, wherein the silicon nitride film comprises a silicon:nitrogen ratio of at least about 3.1:4.

11. The process of claim 1, wherein the silicon nitride film comprises a silicon:nitrogen ratio of greater than or equal to about 1:1.

12. The process of claim 1, wherein the pulse sequence comprises:
hexachlordisilane/purge/tetrakis(dimethylamino)silane/purge/(NH₃+H₂)/purge.

13. The process of claim 1, wherein the pulse sequence comprises:
hexachlorodisilane/purge/(tetrakis(dimethylamino)silane+H₂)/purge/NH₃/purge.

14. The process of claim 1, wherein the pulse sequence comprises:
hexachlorodisilane/purge/tetrakis(dimethylamino)silane/purge/NH₃/purge.

15. The process of claim 2, wherein the pulse sequence comprises
hexachlordisilane/purge/(NH₃+H₂)/purge.

16. The process of claim 1, wherein the pulse sequence comprises hexachlorodisilane, tetrakis(dimethylamino)silane, and a mixture of ammonia and hydrogen.

17. The process of claim 1, further comprising at least one pulse sequence comprising plasma ammonia or plasma hydrogen.

18. The process of claim 1, wherein the silicon nitride film has a conformality of at least about 95%.

19. A microelectronic device structure having thereon a silicon nitride film, the structure having at least one substructure having an aspect ratio of about greater than about 10, wherein the silicon nitride film has a conformality of at least about 95%, and a silicon to nitride ratio of at least about 1.04:1 to about 1.12:1.

20. The device of claim 19, wherein the aspect ratio is from about 10 to about 500.
